(19) United States
(12) Patent Application Publication
(10) Pub. No.: US 2026/0215094 A1
(43) Pub. Date: Jul. 23, 2026

(54) DISPLAY APPARATUS HAVING A CHARGE GENERATION LAYER

(71) Applicant: LG Display Co., Ltd., Seoul (KR)

(72) Inventors: Hak Min LEE, Paju-si (KR); Hoon Sok SON, Paju-si (KR); Beom Gon JO, Paju-si (KR); Min Ki KIM, Paju-si (KR)

(73) Assignee: LG Display Co., Ltd., Seoul (KR)

(21) Appl. No.: 19/347,022

(22) Filed: Oct. 1, 2025

(30) Foreign Application Priority Data
Jan. 23, 2025 (KR) 10-2025-0010395

(51) Int. Cl. H10K 59/122; H10K 59/00; H10K 59/35

(52) U.S. Cl. CPC H10K 59/122; H10K 59/353; H10K 59/771

(57) ABSTRACT

A display apparatus can a plurality of pixel areas. A first emission area, a second emission area and a third emission area can be defined in each pixel area. A light-emitting device can be disposed in each emission area. Each of the light-emitting devices can include a first emission stack, a charge generation layer and a second emission stack, which are sequentially stacked. A planarization layer can be disposed between the device substrate and the light-emitting devices. The planarization layer can include a separation trench disposed between the first emission area and the second emission area of each pixel area and an opening overlapping with the third emission area of each pixel area. The charge generation layer can be separated by the separation trench and a thickness difference due to the opening. Thus, in the display apparatus, leakage in a current due to the charge generation layer can be prevented.

### CROSS-REFERENCE TO RELATED APPLICATIONS

This application claims the benefit of and priority to Korean Patent Application No. 10-2025-0010395, filed on Jan. 23, 2025, the entire contents of which are incorporated herein by reference for all purposes as if fully set forth herein.

### BACKGROUND

### 1. Technical Field

The present disclosure relates to a display apparatus, and particularly to, for example, without limitation, a display apparatus in which each of light-emitting devices includes a charge generation layer.

### 2. Description of Related Art

Generally, a display apparatus provides an image to a user. For example, the display apparatus can include a light-emitting device. The light-emitting device can emit light displaying a specific color. For example, the light-emitting device can include a light-emitting unit disposed between a first electrode and a second electrode. The light-emitting unit can include emission stacks. Each of the emission stacks can generate light. For example, a charge generation layer can be disposed between the emission stacks. Thus, in the display apparatus, the image provided to the user can include various colors.

The description of related art should not be considered prior art merely because it is mentioned in or associated with this section. The description of related art includes information that describes one or more aspects of the subject technology, and the description in this section does not limit the scope of the invention.

### SUMMARY

Accordingly, the present disclosure is directed to a display apparatus that substantially obviates one or more problems due to limitations and disadvantages of the related art.

An aspect of the present disclosure is to provide a display apparatus capable of preventing the leakage of the current due to the charge generation layer.

Additional advantages, aspects, and features of the disclosure will be set forth in part in the description which follows and in part will become apparent to those having ordinary skill in the art upon examination of the following or may be learned from practice of the disclosure. Various aspects and other advantages of the disclosure may be realized and attained by the structure particularly pointed out in the written description and claims hereof as well as the appended drawings.

To achieve these aspects and other advantages and in accordance with one or more aspects of the present disclosure, as embodied and broadly described herein, there is provided a display apparatus comprising a device substrate. Fences, a planarization layer and light-emitting device are disposed on the device substrate. The fences define a first emission area, a second emission area and a third emission area in each pixel area. The light-emitting devices overlap with the first emission area, the second emission area and the third emission area of each pixel area. The planarization layer includes a separation trench disposed between the first emission area and the second emission area of each pixel area and an opening overlapping with the third emission area of each pixel area. Each of the light-emitting devices includes a first emission stack, a first charge generation layer and a second emission stack, which are sequentially stacked. The separation trench separates the first charge generation layer between the first emission area and the second emission area of each pixel area. The first charge generation layer between the first emission area and the third emission area of each pixel area is separated by a thickness difference due to the opening. The first charge generation layer between the second emission area and the third emission area of each pixel area is separated by a thickness difference due to the opening.

Light generated by the second emission stack can display a different color from light generated by the first emission stack. The first emission area, the second emission area and the third emission area of each pixel area can realize different colors.

The second emission area of each pixel area can be disposed side by side with the first emission area of the corresponding pixel area in a first direction. The third emission area of each pixel area can be disposed side by side with the first emission area and the second emission area of the corresponding pixel area in a second direction perpendicular to the first direction.

The separation trench can extend in the second direction. A length of the separation trench in the second direction can be longer than a length of the first emission area of each pixel area in the second direction and a length of the second emission area of each pixel area in the second direction.

Each of the first emission area and the second emission area in each pixel area can have a length in the second direction longer than a length in the first direction. The third emission area of each pixel area can have a length in the second direction shorter than a length in the first direction.

The first charge generation layer in the third emission area of each pixel area can be in contact with the first charge generation layer in the third emission area of the pixel area adjacent in the first direction.

The device substrate can include a display area and a bezel area. The pixel areas can be disposed in the display area. The bezel area can be disposed outside the display area. The device substrate can include a pad area on the bezel area. The first charge generation layer can be electrically connected to the pad area.

A first reflective electrode, a second reflective electrode and a third reflective electrode can be disposed between the device substrate and the light-emitting devices. The first reflective electrode can overlap with the first emission area of each pixel area. The second reflective electrode can overlap with the second emission area of each pixel area. The second reflective electrode can be disposed on a different layer from the first reflective electrode. The third reflective electrode can overlap with the third emission area of each pixel area. The third reflective electrode can be disposed on a same layer as the first reflective electrode.

A sub-bank layer can be disposed between the device substrate and the planarization layer. The sub-bank layer can overlap with the third emission area of each pixel area. The sub-bank layer can include a penetrating hole overlapping with at least one of the third reflective electrode. An edge of third reflective electrode can be covered by the sub-bank layer.

The light-emitting devices can include a first light-emitting device, a second light-emitting device and a third light-emitting device. The first light-emitting device can overlap with the first emission area of each pixel area. The second light-emitting device can overlap with the second emission area of each pixel area. The third light-emitting device can overlap with the third emission area of each pixel area. A distance between the third reflective electrode and the third light-emitting device can be different from a distance between the first reflective electrode and the first light-emitting device.

A distance between the device substrate and the second light-emitting device can be a same as a distance between the device substrate and the first light-emitting device. A distance between the device substrate and the third light-emitting device can be different from the distance between the device substrate and the second light-emitting device.

Each of the light-emitting devices can include a first electrode disposed and a second electrode. The first electrode can be disposed between the device substrate and the first emission stack. The second emission stack can be disposed between the first charge generation layer and the second electrode. The first electrode of the second light-emitting device can include a same material as the first electrode of the first light-emitting device. The first electrode of the third light-emitting device can include a same material as the first electrode of the second light-emitting device. A distance between the device substrate and the second electrode of the third light-emitting device can be smaller than a distance between the device substrate and the second electrode of the first light-emitting device and a distance between the device substrate and the second electrode of the second light-emitting device.

The first electrode of the third light-emitting device can be in contact with an upper surface of the third reflective electrode opposite to the device substrate.

Each of the light-emitting devices can include a second charge generation layer and a third emission stack. The second charge generation layer can be disposed in the second emission area. The third emission stack can be disposed on the second charge generation layer. The second charge generation layer in the second emission area of each pixel area can be in contact with the second charge generation layer in the first emission area of the corresponding pixel area. The second charge generation layer in the third emission area of each pixel area can be in contact with the second charge generation layer in the first emission area of the corresponding pixel area and the second charge generation layer in the second emission area of the corresponding pixel area.

The third emission stack generates light can display a different color from the first emission stack and the second emission stack.

An encapsulation structure can be disposed on the light-emitting devices. A first color filter and a second color filter can be disposed on the encapsulation structure. The first color filter can overlap with the first emission area of each pixel area. The second color filter can overlap with the second emission area of each pixel area. An optical insulating layer can be disposed on the first color filter and the second color filter. Light passing through the second color filter can display a different color from light passing through the first color filter. The optical insulating layer can be in contact with an upper surface of the encapsulation structure opposite to the device substrate in the third emission area of each pixel area.

The third emission area of each pixel area can be a blue emission area realizing a blue color.

Additional features, advantages, and aspects of the present disclosure are set forth in part in the description that follows and in part will become apparent from the present disclosure or may be learned by practice of the inventive concepts provided herein. Other features, advantages, and aspects of the present disclosure may be realized and attained by the descriptions provided in the present disclosure, or derivable therefrom, and the claims hereof as well as the drawings. It is intended that all such features, advantages, and aspects be included within this description, be within the scope of the present disclosure, and be protected by the following claims. Nothing in this section should be taken as a limitation on those claims. Further features, advantages, and aspects are discussed below in conjunction with embodiments of the present disclosure.

It is to be understood that both the foregoing description and the following description of the present disclosure are examples, and are intended to provide further explanation of the disclosure as claimed.

### BRIEF DESCRIPTION OF THE DRAWINGS

The accompanying drawings, which are included to provide a further understanding of the present disclosure, are incorporated in and constitute a part of this present disclosure, illustrate aspects and embodiments of the present disclosure, and together with the description serve to explain principles and examples of the disclosure. In the drawings:

FIG. 1 is a view schematically showing a display apparatus according to an embodiment of the present disclosure;

FIG. 2 is an enlarged view of K region in FIG. 1;

FIG. 3 is a view showing a circuit of a sub-pixel in the display apparatus according to the embodiment of the present disclosure;

FIG. 4 is a view taken along I-I′ of FIG. 2;

FIG. 5 is an enlarged view of R1 region in FIG. 4;

FIGS. 6 to 14 are views showing a method of forming the display apparatus according to the embodiment of the present disclosure; and

FIGS. 15 to 20 are views showing the display apparatus according to another embodiment of the present disclosure.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and/or convenience.

### DETAILED DESCRIPTION

Hereinafter, details related to the above aspects, technical configurations, and operational effects of the embodiments of the present disclosure will be clearly understood by the following detailed description with reference to the drawings, which illustrate some embodiments of the present disclosure. Here, the embodiments of the present disclosure are provided in order to allow the technical sprit of the present disclosure to be satisfactorily transferred to those skilled in the art, and thus the present disclosure may be embodied in other forms and is not limited to the embodiments described below.

In addition, the same or extremely similar elements may be designated by the same reference numerals throughout the specification and in the drawings, the lengths and thickness of layers and regions may be exaggerated for convenience. It will be understood that, when a first element is referred to as being “on” a second element, although the first element may be disposed on the second element so as to come into contact with the second element, a third element may be interposed between the first element and the second element.

Here, terms such as, for example, “first” and “second” may be used to distinguish any one element with another element. However, the first element and the second element may be arbitrary named according to the convenience of those skilled in the art without departing the technical sprit of the present disclosure.

The terms used in the specification of the present disclosure are merely used in order to describe particular embodiments, and are not intended to limit the scope of the present disclosure. For example, an element described in the singular form is intended to include a plurality of elements unless the context clearly indicates otherwise. For example, an element may be one or more elements. An element may include a plurality of elements. The word “exemplary” is used to mean serving as an example or illustration. Embodiments are example embodiments. Aspects are example aspects. In one or more implementations, “embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

In addition, in the specification of the present disclosure, it will be further understood that the terms “comprises” and “includes” specify the presence of stated features, integers, steps, operations, elements, components, and/or combinations thereof, but do not preclude the presence or addition of one or more other features, integers, steps, operations, elements, components, and/or combinations.

And, unless “directly” is used, the terms “connected” and “coupled” may include that two components are “connected” or “coupled” through one or more other components located between the two components.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and should not be interpreted in an idealized or overly formal sense unless expressly so defined herein.

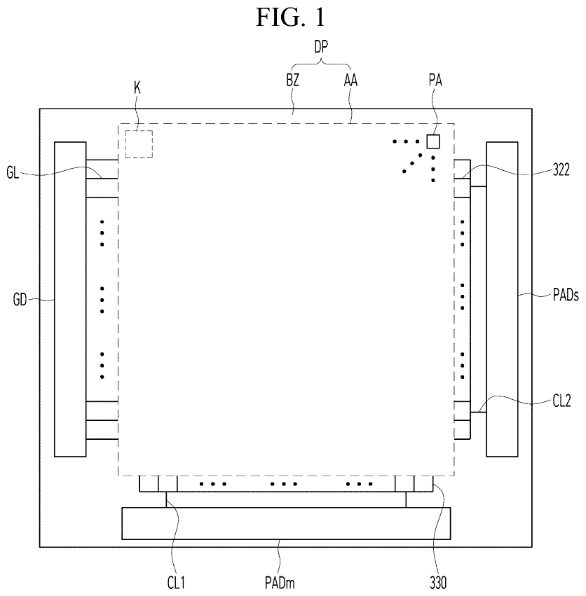

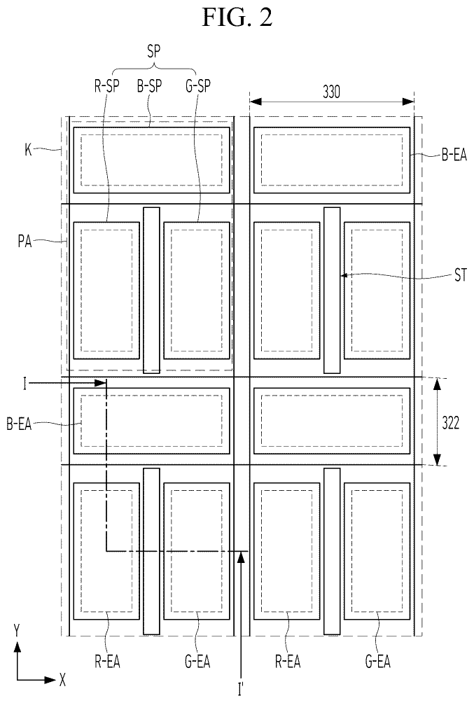

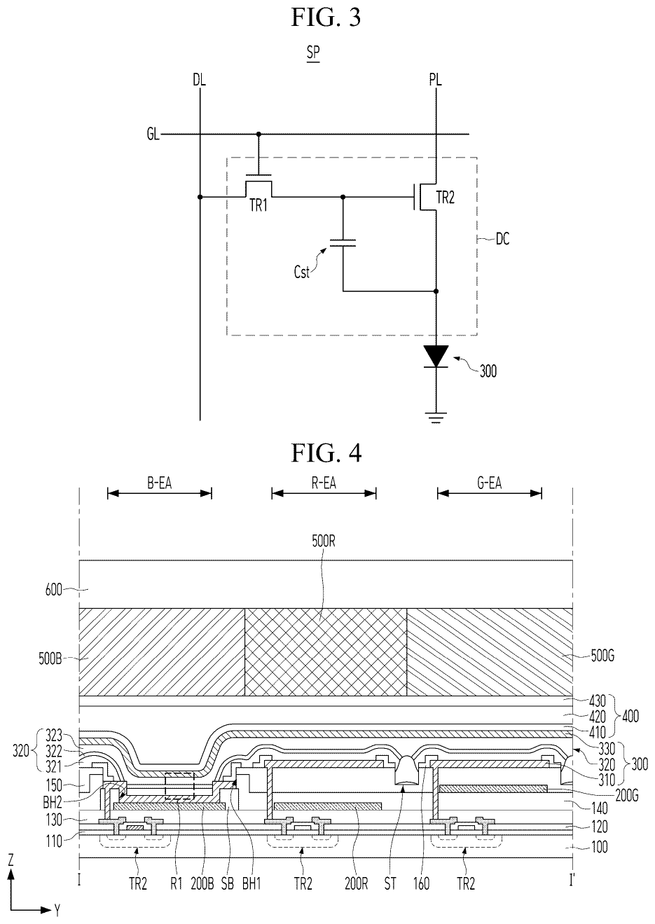

FIG. 1 is a view schematically showing a display apparatus according to an embodiment of the present disclosure. FIG. 2 is an enlarged view of K region in FIG. 1. FIG. 3 is a view showing a circuit of a sub-pixel in the display apparatus according to the embodiment of the present disclosure.

Referring to FIGS. 1 to 3, the display apparatus according to the embodiment of the present disclosure can include a display panel DP. The display panel DP can generate an image provided to a user. For example, the display panel DP can include a plurality of pixel areas PA. The plurality of pixel areas PA can be disposed side by side in a first direction X and a second direction Y. The second direction Y can be a direction perpendicular to the first direction X.

Each of the pixel areas PA can realize various colors. For example, each of the pixel areas PA can include a plurality of sub-pixels SP. Each of the sub-pixels SP can display a specific color. For example, each of the sub-pixel SP can be one of a red sub-pixel R-SP displaying a red color, a green sub-pixel G-SP displaying a green color, and a blue sub-pixel B-SP displaying a blue color. Each of the pixel areas PA can include three sub-pixels SP. For example, the red sub-pixel R-SP, the green sub-pixel G-SP disposed side by side with the red sub-pixel R-SP in the first direction, and a blue sub-pixel B-SP disposed side by side with the red sub-pixel R-SP and the green sub-pixel G-SP in the second direction Y.

Various signals can be applied to each sub-pixel SP through signal wirings GL, DL and PL. For example, a driving circuit DC electrically connected to the signal wirings GL, DL and PL, and a light-emitting device 300 electrically connected to the driving circuit DC can be disposed in each sub-pixel SP. In the display apparatus according to the embodiment of the present disclosure, the light-emitting device 300 of the red sub-pixel R-SP can be a first light-emitting device, the light-emitting device 300 of the green sub-pixel G-SP can be a second light-emitting device, and the light-emitting device 300 of the blue sub-pixel B-SP can be a third light-emitting device.

The signal wirings GL, DL and PL can include a gate line GL applying a gate signal, a data line DL applying a data signal and a power voltage supply ling PL supplying a first power voltage. For example, the driving circuit DC can provide a driving current corresponding to the data signal to the light-emitting device 300 according to the gate signal by using the first power voltage. The driving current provided to the light-emitting device 300 by the driving circuit DC can be maintained for one frame. The driving circuit DC can include a first thin film transistor TR1, a second thin film transistor TR2 and a storage capacitor Cst.

The first thin film transistor TR1 can transmit the data signal to the second thin film transistor TR2 according to the gate signal. For example, the first thin film transistor TR1 can function as a switching thin film transistor. The second thin film transistor TR2 can generate the driving current corresponding to the data signal by using the first power voltage. For example, the second thin film transistor TR2 can function as a driving thin film transistor. An operation of the second thin film transistor TR2 can be maintained by the storage capacitor Cst for one frame. For example, the storage capacitor Cst can be electrically connected to the gate electrode and the source electrode of the second thin film transistor TR2.

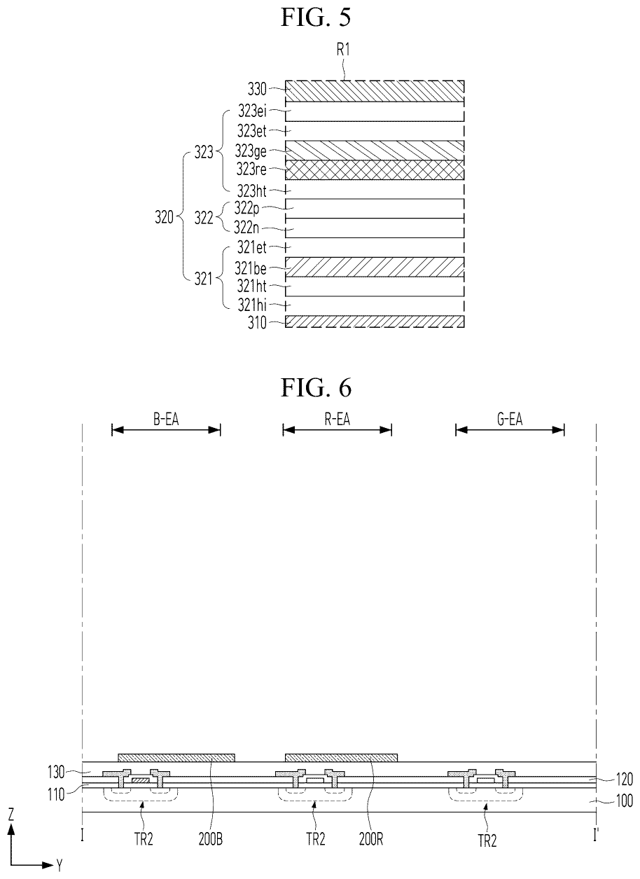

FIG. 4 is a view taken along I-I′ of FIG. 2. FIG. 5 is an enlarged view of R1 region in FIG. 4.

Referring to FIGS. 1 to 5, the display apparatus according to the embodiment of the present disclosure can include a device substrate 100 supporting the driving circuit DC of each sub-pixel SP. The device substrate 100 can include various materials. For example, the device substrate 100 can be a wafer made of a semiconductor material, such as silicon. The driving circuit of each sub-pixel SP can include a region disposed within the device substrate 100. At least one insulating layers 110, 120, 130, 140, 150 and 160 for preventing unintended electrical connection can be disposed on the device substrate 100. For example, a gate insulating layer 110, an interlayer insulating layer 120, a lower planarization layer 130, an intermediate insulating layer 140, an upper planarization layer 150 and fences 160 can be disposed on the device substrate 100.

The gate insulating layer 110 can be disposed on the device substrate 100. The interlayer insulating layer 120 can be disposed on the gate insulating layer 110. The lower planarization layer 130 can be disposed on the interlayer insulating layer 120. The lower planarization layer 130 can include a material having a higher fluidity than the gate insulating layer 110 and the interlayer insulating layer 120. For example, the gate insulating layer 110 and the interlayer insulating layer 120 can include an inorganic insulating material, and the lower planarization layer 130 can include an organic insulating material.

The intermediate insulating layer 140 can be disposed on the lower planarization layer 130. The upper planarization layer 150 can be disposed on the intermediate insulating layer 140. The fences 160 can be disposed on the upper planarization layer 150. The intermediate insulating layer 140, the upper planarization layer 150 and the fences 160 can include an insulating material. The fences 160 can define an emission area R-EA, G-EA and B-EA in each sub-pixel SP. For example, in the display apparatus according to the embodiment of the present disclosure, a red emission area R-EA can be defined in the red sub-pixel R-SP of each pixel area PA by the fences 160, a green emission area G-EA can be defined in the green sub-pixel G-SP of each pixel area PA by the fences 160, and a blue emission area B-EA can be defined in the blue sub-pixel B-SP of each pixel area PA by the fences 160. In the display apparatus according to the embodiment of the present disclosure, the red emission area R-EA of each pixel area PA can be a first emission area, the green emission area G-EA of each pixel area PA can be a second emission area, and the blue emission area B-EA of each pixel area PA can be a third emission area.

The light-emitting device 300 of each sub-pixel SP can be disposed on a portion of the upper planarization layer 150 overlapping with the emission area R-EA, G-EA and B-EA of the corresponding sub-pixel SP. For example, in the display apparatus according to the embodiment of the present disclosure, the light-emitting devices 300 can include a first light-emitting device overlapping with the red emission area R-EA of each pixel area PA, a second light-emitting device overlapping with the green emission area G-EA of each pixel area PA, and a third light-emitting device overlapping with the blue emission area B-EA of each pixel area PA. The light-emitting device 300 of each sub-pixel SP can emit light displaying a specific color. For example, the light-emitting device 300 of each sub-pixel SP can include a first electrode 310, a light-emitting unit 320 and a second electrode 330, which are sequentially stacked.

The first electrode 310 and the second electrode 330 can include a conductive material. The second electrode 330 can include a different material from the first electrode 310. For example, the first electrode 310 can be a transparent electrode made of a transparent conductive material, such ITO and IZO, and the second electrode 330 can be a translucent electrode, in which a metal, such as silver (Ag) and magnesium(Mg) is thinly formed. The first electrode 310 of each sub-pixel SP can be electrically connected to the driving circuit DC of the corresponding sub-pixel SP. The first electrode 310 of each sub-pixel SP can be insulated from the first electrode 310 of adjacent sub-pixel SP. For example, an edge of the first electrode 310 on each sub-pixel SP can be covered by the fences 160.

The light-emitting unit 320 of each sub-pixel SP can generate light having luminance corresponding to a voltage difference between the first electrode 310 and the second electrode 330 of the corresponding sub-pixel SP. For example, the light-emitting unit 320 of each sub-pixel SP can be in direct contact with a portion of the first electrode 310 exposed by the fences 160 and the second electrode 330 within the emission area R-EA, G-EA and B-EA of the corresponding sub-pixel SP. Thus, in the display apparatus according to the embodiment of the present disclosure, light can be generated within the emission area R-EA, G-EA and B-EA defined in each sub-pixel SP by the fences 160. For example, a region disposed between the emission areas R-EA, G-EA and B-EA can be a non-emission area, in which light is not generated. In the display apparatus according to the embodiment of the present disclosure, the red emission area R-EA of each pixel area PA can be a first emission area, the green emission area G-EA of each pixel area PA can be a second emission area, and the blue emission area B-EA of each pixel area PA can be a third emission area.

The light-emitting unit 320 of each sub-pixel SP can include a first emission stack 321, a charge generation layer 322 and a second emission stack 323, which are sequentially stacked. The charge generation layer 322 can supply electrons or holes to the first emission stack 321 and the second emission stack 323. For example, the charge generation layer 322 can have a stacked structure of a n-type charge generation layer 322n and a p-type charge generation layer 322p. The n-type charge generation layer 322n of each sub-pixel SP can be disposed between the first emission stack 321 and the p-type charge generation layer 322p of the corresponding sub-pixel SP. Thus, in the display apparatus according to the embodiment of the present disclosure, each of the first emission stack 321 and the second emission stack 323 can generate light.

The light generated by the second emission stack 323 of each sub-pixel SP can display a different color from the light generated by the first emission stack 321 of the corresponding sub-pixel SP. The light emitted from the light-emitting unit 320 of each sub-pixel SP can display a same color as the light emitted from the light-emitting unit 320 of adjacent sub-pixel SP. For example, in the display apparatus according to the embodiment of the present disclosure, the first emission stack 321 can include a hole injection layer 321hi, a first hole transport layer 321ht, a blue emission material layer 321be, and a first electron transport layer 321et, which are sequentially stacked, and the second emission stack 323 can include a second hole transport layer 323ht, a red emission material layer 323re, a green emission material layer 323ge, a second electron transport layer 323et and an electron injection layer 323ei, which are sequentially stacked. Thus, in the display apparatus according to the embodiment of the present disclosure, the light emitted from the light-emitting unit 320 of each sub-pixel SP can be a white light, in which the light generated by the blue emission material layer 321be, the light generated by the red emission material layer 323re and the light generated by the green emission material layer 323ge are mixed.

A micro-cavity structure emitting light having a specific wavelength can be formed in the emission area R-EA, G-EA and B-EA of each sub-pixel SP. For example, reflective electrodes 200R, 200G and 200B can be disposed between the driving circuit DC and the first electrode 310 of each sub-pixel SP. The reflective electrodes 200R, 200G and 200B can include a material having high reflectance. For example, the reflective electrodes 200R, 200G and 200B can include metal. The reflective electrodes 200R, 200G and 200B can include a red reflective electrode 200R overlapping with the red emission area R-EA of each pixel area PA, a green reflective electrode 200G overlapping with the green emission area G-EA of each pixel area PA, and a blue reflective electrode 200B overlapping with the blue emission area B-EA of each pixel area PA. In the display apparatus according to the embodiment of the present disclosure, the red reflective electrode 200R of each pixel area PA can be a first reflective electrode, the green reflective electrode 200G of each pixel area PA can be a second reflective electrode, and the blue reflective electrode 200B of each pixel area PA can be a third reflective electrode.

The green reflective electrode of each pixel area PA can be disposed on a different layer from the red reflective electrode 200R and the blue reflective electrode 200B of the corresponding pixel area PA. The blue reflective electrode 200B of each pixel area PA can be disposed on a same layer as the red reflective electrode 200R of the corresponding pixel area PA. For example, the red reflective electrode 200R and the bleu reflective electrode 200B of each pixel area PA can be disposed between the lower planarization layer 130 and the intermediate insulating layer 140, and the green reflective electrode 200G of each pixel area PA can be disposed between the intermediate insulating layer 140 and the upper planarization layer 150.

The upper planarization layer 150 can include a separation trench ST between the red emission area R-EA and the green emission area G-EA of each pixel area PA. The separation trench ST can have a shape, in which a portion of the upper planarization layer 150 is removed. The separation trench ST can extend in the second direction Y. For example, a length of the separation trench ST in the second direction Y can be longer than a length of the red emission area R-EA of each pixel area PA in the second direction Y and a length of the green emission area G-EA of each pixel area PA in the second direction Y. Thus, in the display apparatus according to the embodiment of the present disclosure, the charge generation layer 322 can be separated by the separation trench ST between the red emission area R-EA and the green emission area G-EA of each pixel area PA. Therefore, in the display apparatus according to the embodiment of the present disclosure, the leakage of the current through the charge generation layer 322 in the first direction X can be prevented.

The upper planarization layer 150 can include an opening BH1 overlapping with the blue emission area B-EA of each pixel area PA. The opening BH1 can penetrate the intermediate insulating layer 140. The opening BH can overlap with the blue reflective electrode 200B on the blue emission area B-EA of each pixel area PA. For example, the first electrode 310 on the blue emission area B-EA of each pixel area PA can extend into the opening BH1. Thus, in the display apparatus according to the embodiment of the present disclosure, a thickness difference due to the opening BH1 can be formed between the red emission area R-EA and the blue emission area B-EA of each pixel area PA and between the green emission area G-EA and the blue emission area B-EA of each pixel area PA. For example, in the display apparatus according to the embodiment of the present disclosure, the charge generation layer 322 can be separated by the thickness difference due to the opening BH between the red emission area R-EA and the blue emission area B-EA of each pixel area PA and between the green emission area G-EA and the blue emission area B-EA of each pixel area PA. Therefore, in the display apparatus according to the embodiment of the present disclosure, the leakage of the current through the charge generation layer 322 in the second direction Y can be prevented.

A sub-bank layer SB can be disposed within the blue emission area B-EA of each pixel area PA. The sub-bank layer SB can include an insulating material. The sub-bank layer SB can include a material having an etching selectivity with respect to the intermediate insulating layer 140 and the upper planarization layer 150. The sub-bank layer SB can be disposed between the blue reflective electrode 200B and the first electrode 310, which overlap with the blue emission area B-EA of each pixel area PA. The blue reflective electrode 200B of each pixel area PA can be partially exposed by the sub-bank layer SB. For example, the sub-bank layer SB can include a penetrating hole BH2 overlapping with at least portion of the blue reflective electrode 200B in each pixel area PA. The penetrating hole BH2 of the sub-bank layer SB in each pixel area PA can overlap with the opening BH1 of the corresponding pixel area PA. For example, the first electrode 310 on the blue emission area B-EA of each pixel area PA can be in direct contact with the blue reflective electrode 200B of the corresponding pixel area PA in the penetrating hole BH2 of the sub-bank layer SB on the corresponding pixel area PA. An edge of the blue reflective electrode 200B on each pixel area PA can be covered by the sub-bank layer SB. Thus, in the display apparatus according to the embodiment of the present disclosure, a distance between the green reflective electrode 200G and the first electrode 310 in the green emission area G-EA of each pixel area PA can be different from a distance between the red reflective electrode 200R and the first electrode 310 in the red emission area R-EA of the corresponding pixel area PA, and the distance between the red reflective electrode 200R and the first electrode 310 in the red emission area R-EA of each pixel area PA can be different from the blue reflective electrode 200B and the first electrode 310 in the blue emission area B-EA of the corresponding pixel area PA. For example, in the display apparatus according to the embodiment of the present disclosure, a red light can be emitted through the second electrode 330 of the red emission area R-EA of each pixel area PA, a green light can be emitted through the second electrode 330 of the green emission area G-EA of each pixel area PA, and a blue light can be emitted through the second electrode 330 of the blue emission area B-EA of each pixel area PA.

A thickness difference formed between the red emission area R-EA and the blue emission area B-EA of each pixel area PA and between the green emission area G-EA and the blue emission area B-EA of each pixel area PA can be increased by the penetrating hole BHe of the sub-bank layer SB. Thus, in the display apparatus according to the embodiment of the present disclosure, the charge generation layer 322 can be effectively separated between the red emission area R-EA and the blue emission area B-EA of each pixel area PA and between the green emission area G-EA and the blue emission area B-EA of each pixel area PA. Therefore, in the display apparatus according to the embodiment of the present disclosure, the leakage in the current due to the charge generation layer 322 in the second direction Y can be effectively prevented.

A signal applied to the second electrode 330 of each sub-pixel SP can be a same as a signal applied to the second electrode 330 of adjacent sub-pixel SP. For example, a second power voltage can be applied to the second electrode 330 of each sub-pixel SP. The second power voltage can be different from the first power voltage. For example, the first power voltage can be a positive power voltage (VDD), and the second power voltage can be a negative power voltage (VSS). The second electrode 330 of each sub-pixel SP can be electrically connected to the second electrode 330 of the sub-pixel SP adjacent in the second direction Y. For example, the second electrode 330 of each sub-pixel SP can be spaced apart from the second electrode 330 of the sub-pixel SP adjacent in the first direction X.

An encapsulation structure 400 can be disposed on the light-emitting device 300 of each sub-pixel SP. The encapsulation structure 400 can prevent the damage of the light-emitting device 300 in each sub-pixel SP due to the external impact and moisture. The encapsulation structure 400 can have a multi-layer structure. For example, the encapsulation structure 400 can include a first encapsulating layer 410, a second encapsulating layer 420 and a third encapsulating layer 430, which are sequentially stacked. The second encapsulating layer 420 can include a material having a higher fluidity than the first encapsulating layer 410 and the third encapsulating layer 430. For example, the first encapsulating layer 410 and the third encapsulating layer 430 can include an inorganic insulating material, and the second encapsulating layer 420 can include an organic insulating material.

Color filters 500R, 500G and 500B can be disposed on the encapsulation structure 400. Each of the color filters 500R, 500G and 500B can overlap with the emission area R-EA, G-EA and B-EA of one of the sub-pixels SP. The light passing through each color filter 500R, 500G and 500B can display a different color from the light passing through adjacent color filter 500R, 500G and 500B. For example, the color filter 500R, 500G and 500B can include a different material from adjacent color filter 500R, 500G and 500B. The light passing through the color filter 500R, 500G and 500B of each sub-pixel SP can display a same color as the light emitted by the micro-cavity structure formed in the corresponding sub-pixel SP. For example, the color filters 500R, 500G and 500B can include a red color filter 500R overlapping with the red emission area R-EA of each pixel area PA, a green color filter 500G overlapping with the green emission area G-EA of each pixel area PA, and a blue color filter 500B overlapping with the blue emission area B-EA of each pixel area PA. In the display apparatus according to the embodiment of the present disclosure, the red color filter 500R can be a first color filter, the green color filter can be a second color filter, and the blue color filter can be a third color filter. Thus, in the display apparatus according to the embodiment of the present disclosure, the color reproducibility of each sub-pixel SP can be improved.

The color filters 500R, 500G and 500B can be disposed side by side. Each of the color filters 500R, 500G and 500B can have a larger size than the corresponding emission area R-EA, G-EA and B-EA. For example, a side surface of each color filter 500R, 500G and 500B can be in direct contact with a side surface of adjacent color filter 500R, 500G and 500B on the non-emission area. Thus, in the display apparatus according to the embodiment of the present disclosure, the leakage light in which light that does not pass through the color filters 500R, 500G and 500B is emitted can be prevented. Therefore, in the display apparatus according to the embodiment of the present disclosure, the quality of the image provided to the user can be improved.

An optical insulating layer 600 can be disposed on the color filters 500R, 500G and 500B. The optical insulating layer 600 can prevent the damage of the color filters 500R, 500G and 500B due to the external impact. The optical insulating layer 600 can include an insulating material. For example, the optical insulating layer 600 can include an organic insulating material.

Accordingly, the display apparatus according to the embodiment of the present disclosure can comprise the upper planarization layer 150, the fences 160 and the light-emitting devices 300 on the device substrate 100, wherein the light-emitting unit 320 of each light-emitting device 300 can have the first emission stack 321, the charge generation layer 322 and the second emission stack 323, and wherein the upper planarization layer 150 can include the separation trench ST disposed between the red emission area R-EA and the green emission area G-EA of each pixel area and the opening BH1 overlapping with the blue emission area B-EA of each pixel area PA. Thus, in the display apparatus according to the embodiment of the present disclosure, the charge generation can be separated by the separation trench ST between the red emission area R-EA and the green emission area G-EA of each pixel area PA, and the charge generation layer 322 can be separated by a thickness difference due to the opening BH1 between the red emission area R-EA and the blue emission area B-EA of each pixel area PA and between the green emission area G-EA and the blue emission area B-EA of each pixel area PA. That is, in the display apparatus according to the embodiment of the present disclosure, the leakage current through the charge generation layer 322 in the first direction X can be prevented by the separation trench ST, and the leakage current through the charge generation layer 322 in the second direction Y can be prevented by a thickness different due to the opening BH1. Therefore, in the display apparatus according to the embodiment of the present disclosure, the decrease in the quality of the image due to the leakage current can be minimized.

As shown in FIG. 1, the display panel DP of the display apparatus according to the embodiment of the present disclosure can include a display area AA and a bezel area BZ. The plurality of pixel areas PA can be disposed within the display area AA. The bezel area BZ can be disposed outside the bezel area BZ. For example, the display area AA can be surrounded by the bezel area BZ. A gate driver GD electrically connected to the gate line GL, a data driver electrically connected to the data line DL, and a power unit electrically connected to the power voltage supply line PL can be disposed outside the display area AA. At least one of the gate driver GD, the data driver and the power unit can be disposed on the bezel area BZ. For example, the display apparatus according to the embodiment of the present disclosure can be a GIP (Gate-In-Panel) type display apparatus, in which the gate driver GD is formed in the bezel area BZ.

A first pad area PADm, in which an external signal is applied can be disposed in the bezel area BZ. For example, the data driver can be electrically connected to the data line DL through the first pad area PADm. The second electrode 330 of each sub-pixel SP can be electrically connected to the second electrode 330 of the sub-pixel adjacent in the first direction X by a first common wiring CL1 disposed on the bezel area BZ. Thus, in the display apparatus according to the embodiment of the present disclosure, difference in the second power voltage applied to the second electrode 330 of each sub-pixel SP can be minimized. The second electrode 330 of each sub-pixel SP can be electrically connected to the power unit. For example, the display apparatus according to the embodiment of the present disclosure, the first common wiring CL1 connected to the second electrode 330 of each sub-pixel SP can be electrically connected to the power unit through the first pad area PADm.

In the display apparatus according to the embodiment of the present disclosure, the blue emission area B-EA of each pixel area PA can have a planar shape different from the red emission area R-EA and the green emission area G-EA of the corresponding pixel area PA. For example, in the display apparatus according to the embodiment of the present disclosure, the red emission area R-EA and the green emission area G-EA of each pixel area PA can have a planar shape extending in the second direction Y, and the blue emission area B-EA of each pixel area PA can have a planar shape extending in the first direction X, as shown in FIG. 2. The red emission area R-EA and the green emission area G-EA of each pixel area PA can have a length in the second direction Y longer than a length in the first direction X. The blue emission area B-EA of each pixel area PA can have a length in the second direction Y shorter than a length in the first direction X.

The charge generation layer 322 on the blue emission area B-EA of each pixel area PA can extend in the first direction X. For example, the charge generation layer 322 on the blue emission area B-EA of each pixel area PA can be in direct contact with the charge generation layer 322 on the blue emission area B-EA of the pixel area PA adjacent in the first direction X. A second pad area PADs electrically connected to the charge generation layer 322 on the blue emission area B-EA of each pixel area PA can be disposed on the bezel area BZ. The charge generation layer 322 on the blue emission area B-EA of each pixel area PA can be connected to the charge generation layer 322 on the blue emission area B-EA on the pixel area PA adjacent in the second direction by a second common wiring CL2 on the bezel area BZ. Thus, in the display apparatus according to the embodiment of the present disclosure, a signal having a specific voltage can be applied to the charge generation layer 322 on the blue emission area B-EA of each pixel area PA. For example, in the display apparatus according to the embodiment of the present disclosure, the blue light emitted on the blue emission area B-EA of each pixel area PA can have a luminance corresponding to a voltage difference between the first electrode 310 and the charge generation layer 322 on the blue emission area B-EA of the corresponding pixel area PA. Therefore, in the display apparatus according to the embodiment of the present disclosure, a driving voltage of the blue emission area B-EA of each pixel area PA can be improved. And, in the display apparatus according to the embodiment of the present disclosure, characteristics of the blue light emitted from the blue emission area B-EA of each pixel area PA can be improved, and a load applied to the blue emission material layer 321be on the blue emission area B-EA of each pixel area PA can be decreased. That is, in the display apparatus according to the embodiment of the present disclosure, the overall lifespan can be increased.

FIGS. 6 to 14 are views showing a method of forming the display apparatus according to the embodiment of the present disclosure.

The method of forming the display apparatus according to the embodiment of the present disclosure will be described with reference to FIGS. 2 to 4 and 6 to 14. First, as shown in FIGS. 2, 3 and 6, the method of forming the display apparatus according to the embodiment of the present disclosure can include a step of forming the gate insulating layer 110, the interlayer insulating layer 120, the driving circuits DC and the lower planarization layer 130 on the device substrate 100, and a step of forming the red reflective electrode 200R overlapping with the red emission area R-EA of each pixel area PA and the blue reflective electrode 200B overlapping with the blue emission area B-EA of each pixel area PA on the lower planarization layer 130.

Each of the driving circuits DC can include the second thin film transistor TR2. The blue reflective electrode 200B of each pixel area PA can be formed simultaneously with the red reflective electrode 200R of each pixel area PA. For example, a step of forming the red reflective electrode 200R and the blue reflective electrode 200B of each pixel area PA can include a step of forming a conductive layer on the lower planarization layer 130 using a material having a high reflectance and a step of patterning the conductive layer.

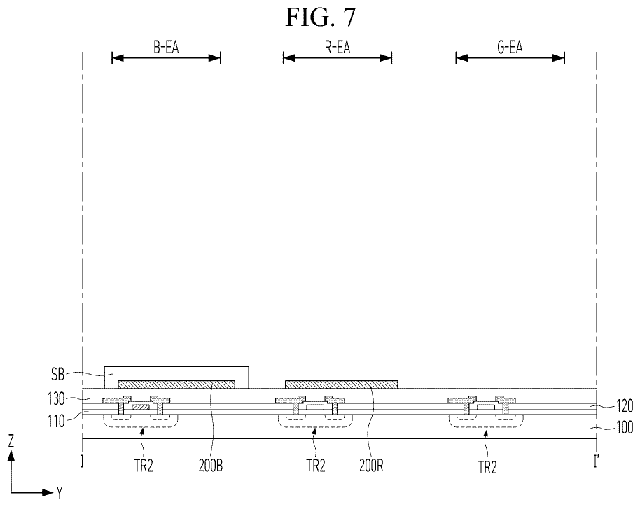

As shown in FIG. 7, the method of forming the display apparatus according to the embodiment of the present disclosure can include a step of the sub-bank layer SB covering the blue reflective electrode 200B of each pixel area PA on the lower planarization layer 130.

The sub-bank layer SB can be formed in the blue emission area B-EA of each pixel area PA. For example, the red reflective electrode 200R of each pixel area PA can be spaced apart from the sub-bank layer SB. The sub-bank layer SB can't overlap with the red emission area R-EA and the green emission area G-EA of each pixel area PA.

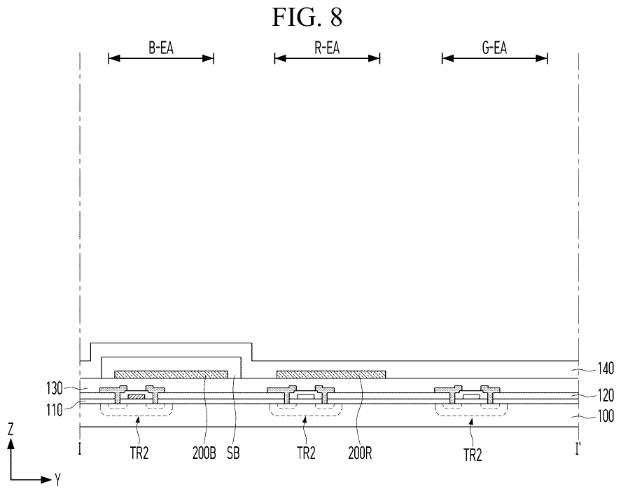

As shown in FIG. 8, the method of forming the display apparatus according to the embodiment of the present disclosure can include a step of forming the intermediate insulating layer 140 on the device substrate 100, in which the sub-bank layer SB is formed.

The red reflective electrode 200R of each pixel area PA can be covered by the intermediate insulating layer 140. The intermediate insulating layer 140 can be formed of a material having an etch selectivity with respect to the sub-bank layer SB.

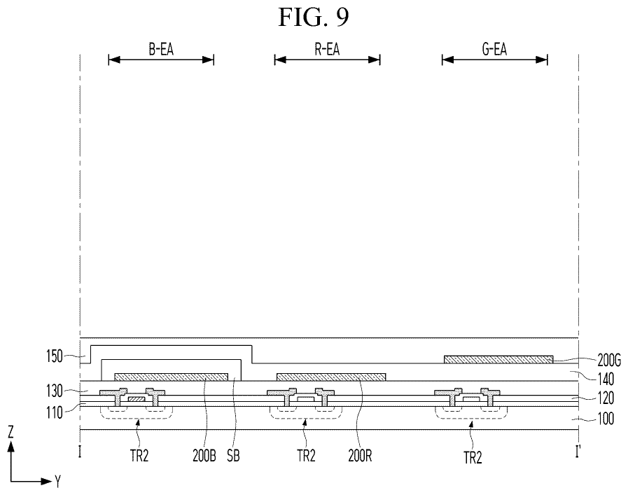

As shown in FIG. 9, the method of forming the display apparatus according to the embodiment of the present disclosure can include a step of forming the green reflective electrode 200G overlapping with the green emission area G-EA of each pixel area on the intermediate insulating layer 140, and a step of forming the upper planarization layer 150 covering the green reflective electrode 200G of each pixel area PA.

The upper planarization layer 150 can include a region overlapping with the red emission area R-EA and the blue emission area B-EA of each pixel area PA. For example, the upper planarization layer 150 can be formed on an entire surface of the device substrate 100, in which the green reflective electrode 200G of each pixel area PA is formed.

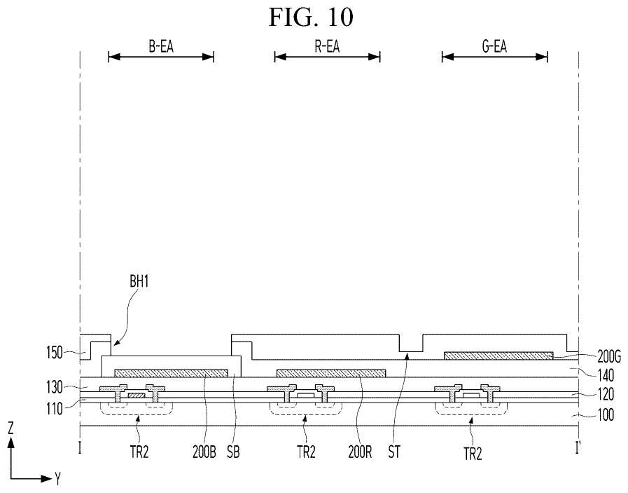

As shown in FIG. 10, the method of forming the display apparatus according to the embodiment of the present disclosure can include a step of forming the separation trench ST in a portion of the upper planarization layer 150 disposed between the red emission area R-EA and the green emission area G-EA of each pixel area PA, and a step of forming the opening BH1 exposing at least portion of the sub-bank layer SB overlapping with the blue emission area B-EA of each pixel area PA.

The opening BH1 can overlap with a portion of the upper planarization layer 150 disposed on the blue emission area B-EA of each pixel area PA. A portion of the intermediate insulating layer 140 overlapping with the blue emission area B-EA of each pixel area PA can be removed in a process of forming the opening BH1. For example, the opening BH1 can penetrate a portion of the intermediate insulating layer 140 and a portion of the upper planarization layer 150 overlapping with the blue emission area B-EA of each pixel area PA.

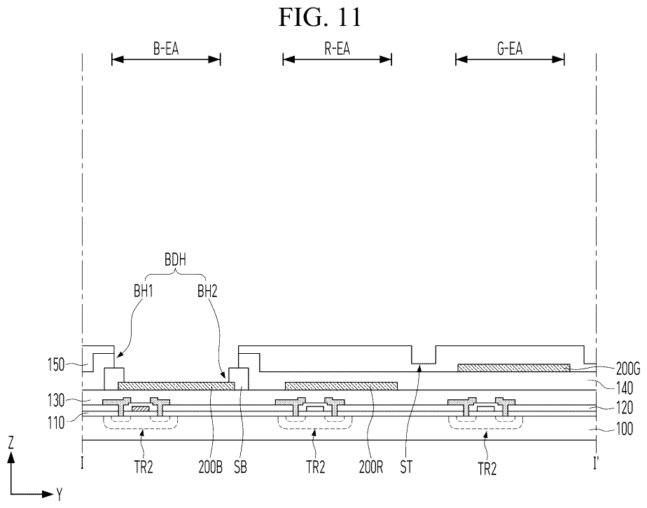

As shown in FIG. 11, the method of forming the display apparatus according to the embodiment of the present disclosure can include a step of forming the penetrating hole BH2 in a portion of the sub-bank layer SB exposed by the opening BH1.

The penetrating hole BH2 can be formed to a smaller size than the opening BH1. For example, the penetrating hole BH2 can be formed in the opening BH1. The opening BH1 and the penetrating hole BH2 can constitute a blue emission defining hole BDH.

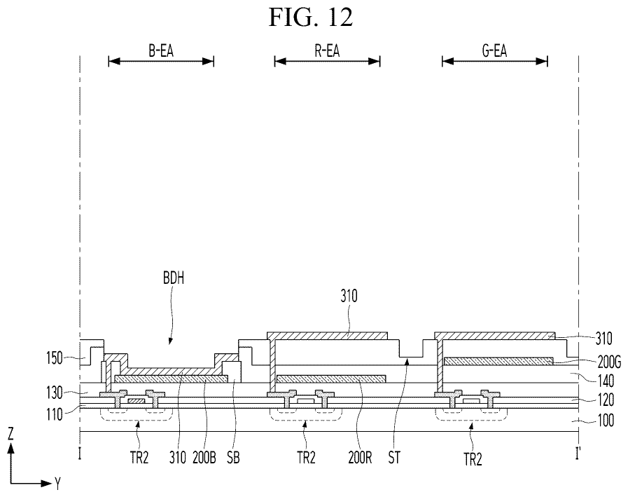

As shown in FIG. 12, the method of forming the display apparatus according to the embodiment of the present disclosure can include a step of forming the first electrodes 310 overlapping with the emission areas R-EA, G-EA and B-EA of each pixel area PA on the device substrate 100, in which the blue emission defining hole BDH is formed.

The first electrode 310 formed on the red emission area R-EA of each pixel area PA and the first electrode 310 formed on the green emission area G-EA of each pixel area PA can be in direct contact with an upper surface of the upper planarization layer 150 opposite to the device substrate 100. The first electrode 310 formed on the blue emission area B-EA of each pixel area PA can be in direct contact with the blue reflective electrode 200B of the corresponding pixel area PA exposed by the blue emission defining hole BDH. Thus, in the method of forming the display apparatus according to the embodiment of the present disclosure, a thickness difference due to the blue emission defining hole BDH can be formed between the red emission area R-EA and the blue emission area B-EA of each pixel area PA and between the green emission area G-EA and the blue emission area B-EA of each pixel area PA.

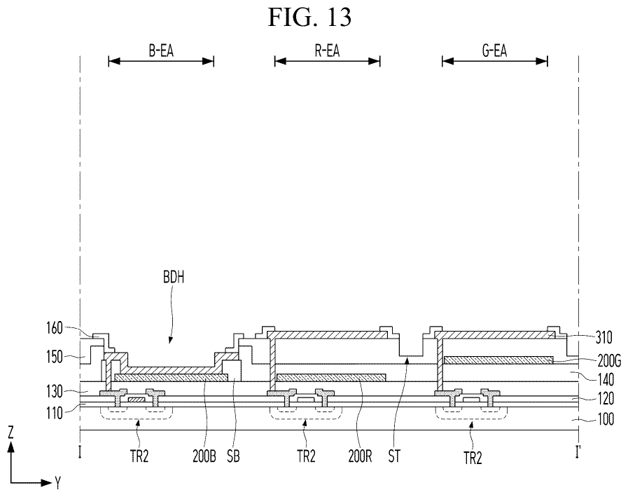

As shown in FIG. 13, the method of forming the display apparatus according to the embodiment of the present disclosure can include a step of forming the fences 160 on the device substrate 100, in which the first electrodes 310 of each pixel area PA are formed.

The fences 160 can partially expose the first electrode 310 formed on the red emission area R-EA of each pixel area PA, the first electrode 310 formed on the green emission area G-EA of each pixel area PA, and the first electrode 310 formed on the blue emission area B-EA of each pixel area PA. For example, an edge of the first electrode 310 formed on the red emission area R-EA of each pixel area PA, an edge of the first electrode 310 formed on the green emission area G-EA of each pixel area PA, and an edge of the first electrode 310 formed on the red emission area R-EA of each pixel area PA can be covered by the fences 160.

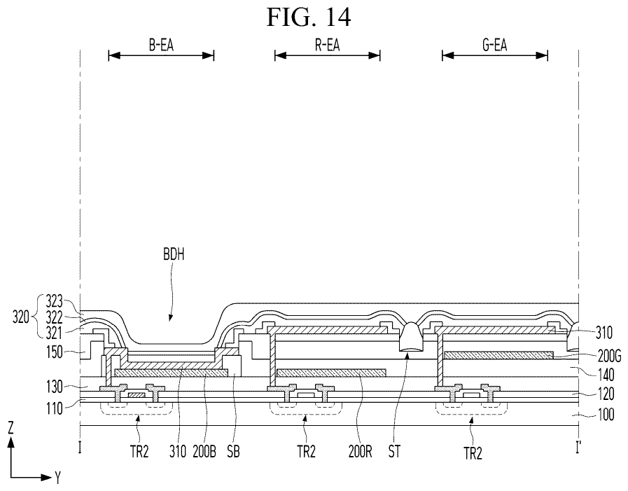

As shown in FIG. 14, the method of forming the display apparatus according to the embodiment of the present disclosure can include a step of forming the light-emitting unit 320 on the device substrate 100, in which the fences 160 are formed.

The step of forming the light-emitting unit 320 can include a step of forming the first emission stack 321, a step of forming the charge generation layer 322 on the first emission stack 321, and a step of forming the second emission stack 323 on the charge generation layer 322. The first emission stack 321 and the charge generation layer 322 can be separated by the separation trench ST between the red emission area R-EA and the green emission area G-EA of each pixel area. The first emission stack 321 and the charge generation layer 322 can be separated by a thickness difference due to the blue emission defining hole BDH between the red emission area R-EA and the blue emission area B-EA of each pixel area PA and between the green emission area G-EA and the blue emission area B-EA of each pixel area PA. That is, in the method of forming the display apparatus according to the embodiment of the present disclosure, the charge generation layer 322 on the red emission area R-EA of each pixel area PA, the charge generation layer 322 on the green emission area G-EA of each pixel area PA, and the charge generation layer 322 on the blue emission area B-EA of each pixel area PA can be separated from each other, without additional process. Therefore, in the method of forming the display apparatus according to the embodiment of the present disclosure, the process efficiency can be improved.

The second emission stack 323 on the green emission area G-EA of each pixel area PA can be connected to the second emission stack 323 on the red emission area R-EA of the corresponding pixel area PA. For example, an air-gap can be formed in the separation trench ST. The second emission stack 323 on the blue emission area B-EA of each pixel area PA can be in direct contact with the second emission stack 323 on the red emission area R-EA of the corresponding pixel area PA and the second emission stack 323 on the green emission area G-EA of the corresponding pixel area PA.

As shown in FIG. 4, the method of forming the display apparatus according to the embodiment of the present disclosure can include a step of forming the second electrode 330 on the light-emitting unit 320 to form the light-emitting devices 300, a step of forming the encapsulation structure 400 on the light-emitting devices 300, a step of forming the color filters 500R, 500G and 500B on the encapsulation structure 400, and a step of forming the optical insulating layer 600 on the color filters 500R, 500G and 500B.

Accordingly, in the method of forming the display apparatus according to the embodiment of the present disclosure, the charge generation layer 322 can be separated by the separation trench ST formed in a portion of the upper planarization layer 150 disposed between the red emission area R-EA and the green emission area G-EA of each pixel area PA and the opening BH1 formed in a portion of the upper planarization 150 overlapping with the blue emission area B-EA of each pixel area PA. Thus, in the method of forming the display apparatus according to the embodiment of the present disclosure, a process for preventing the leakage current through the charge generation layer 322 in the first direction X and the second direction Y can be simplified. Therefore, in the method of forming the display apparatus according to the embodiment of the present disclosure, the production energy can be reduced by process optimization.

The display apparatus according to the embodiment of the present disclosure is described that the driving circuit DC of each sub-pixel SP consists of the first thin film transistor TR1, the second thin film transistor TR2 and the storage capacitor Cst. However, in the display apparatus according to another embodiment of the present disclosure, the driving circuit DC of each sub-pixel SP can include a driving thin film transistor and a plurality of switching thin film transistors. For example, in the display apparatus according to another embodiment of the present disclosure, the driving circuit DC of each sub-pixel SP can further include a third thin film transistor to initialize the storage capacitor Cst of the corresponding sub-pixel SP according to the gate signal. Thus, in the display apparatus according to another embodiment of the present disclosure, the degree of freedom in the configuration of each driving circuit DC can be improved.

The display apparatus according to the embodiment of the present disclosure is described that the device substrate 100 is a wafer made of a semiconductor material, such as silicon. However, in the display apparatus according to another embodiment of the present disclosure, the device substrate 100 can include glass or plastic. The driving circuit DC of each sub-pixel SP can be formed on a buffer insulating layer covering an upper surface of the device substrate 100. Thus, in the display apparatus according to another embodiment of the present disclosure, the degree of freedom in the material of the device substrate 100 and the configuration of each driving circuit DC can be improved.

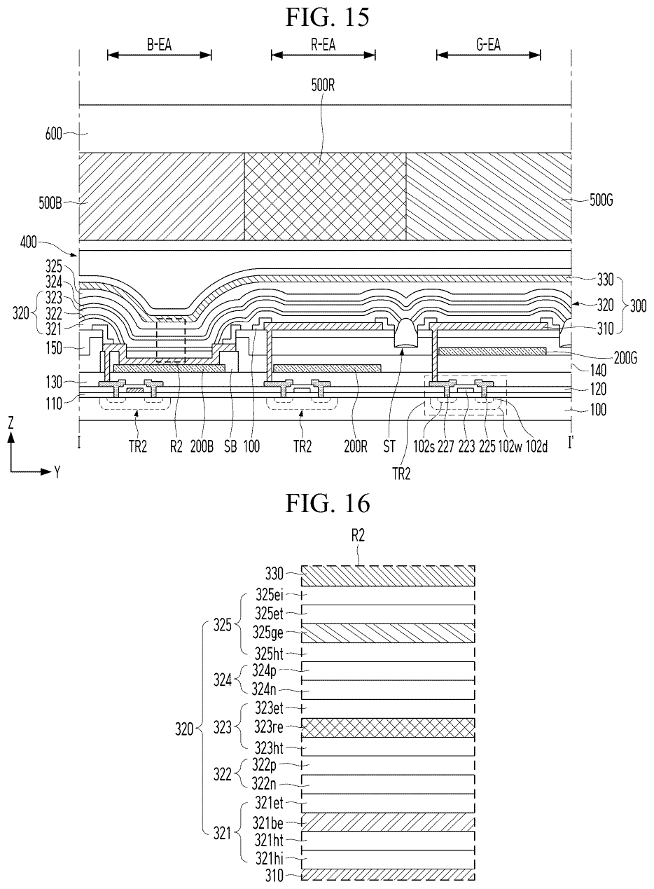

The display apparatus according to the embodiment of the present disclosure is described that the first emission stack 321 includes the blue emission material layer 321be, and the second emission stack 323 includes the red emission material layer 323re and the green emission material layer 323ge. However, in the display apparatus according to another embodiment of the present disclosure, the light-emitting unit 320 can include a plurality of charge generation layers 322. For example, in the display apparatus according to another embodiment of the present disclosure, the light-emitting unit 320 can include the first emission stack 321, a first charge generation layer 322, the second emission stack 323, a second charge generation layer 324 and a third emission stack 325, as shown in FIGS. 15 and 16. The first emission stack 321 can include a blue emission material layer 321be, the second emission stack 323 can include a red emission material layer 323re, and the third emission stack 325 can include a green emission material layer 325ge. The second charge generation layer 324 can't be separated by the separation trench ST and a thickness difference due to the opening BH1. Thus, in the display apparatus according to another embodiment of the present disclosure, the degree of freedom in the configuration of the light-emitting unit 320 can be improved.

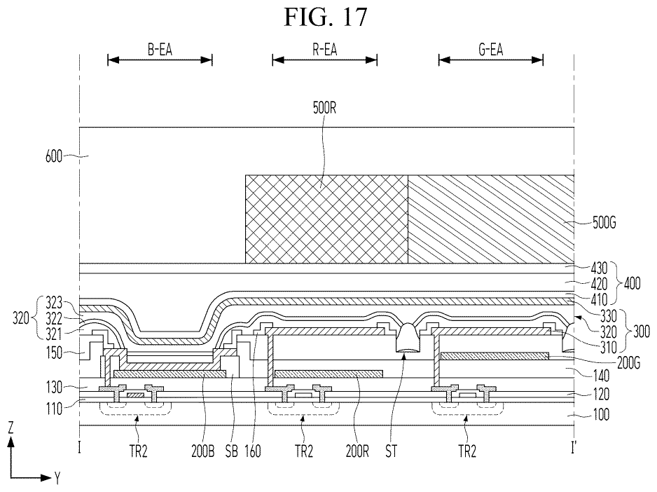

The display apparatus according to the embodiment of the present disclosure is described that each of the color filters 500R, 500G and 500B is disposed on one of the emission areas R-EA, G-EA and B-EA. However, in the display apparatus according to another embodiment of the present disclosure, at least one of the color filters 500R, 500G and 500B can be omitted. For example, in the display apparatus according to another embodiment of the present disclosure, the optical insulating layer 600 can be in direct contact with an upper surface of the encapsulation structure 400 opposite to the device substrate 100 on the blue emission area B-EA of each pixel area PA, as shown in FIG. 17. That is, in the display apparatus according to another embodiment of the present disclosure, a step of forming the blue color filters 500B can be omitted. Thus, in the display apparatus according to another embodiment of the present disclosure, the process efficiency can be improved.

The display apparatus according to the embodiment of the present disclosure is described that the blue emission area B-EA of each pixel area PA is driven, individually. However, in the display apparatus according to another embodiment of the present disclosure, at least one of the emission areas R-EA, G-EA and B-EA in each pixel area PA can be independently controlled. For example, in the display apparatus according to another embodiment of the present disclosure, the separation trench ST can be disposed between the blue emission area B-EA and the green blue emission area G-EA of each pixel area PA, and a thickness difference due to the opening BH1 can be formed between the blue emission area B-EA and the red emission area R-EA of each pixel area PA and between the green emission area G-EA and the red emission area R-EA of each pixel area PA. Thus, in the display apparatus according to another embodiment of the present disclosure, the charge generation layer 322 on the red emission area R-EA of each pixel area PA can be electrically connected to the charge generation layer 322 on the red emission area R-EA of the pixel area PA adjacent in the first direction X. That is, in the display apparatus according to another embodiment of the present disclosure, the red light emitted from the red emission area R-EA of each pixel area PA can be independently controlled. Therefore, in the display apparatus according to another embodiment of the present disclosure, the degree of freedom in the configuration of each pixel area PA can be improved, and the overall lifespan can be improved.

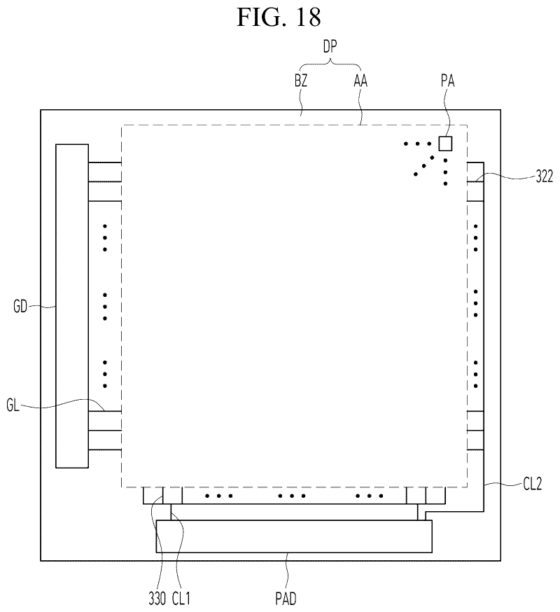

The display apparatus according to the embodiment of the present disclosure is described that the first pad area PADm and the second pad area PADs are disposed on the bezel area bZ. However, in the display apparatus according to another embodiment of the present disclosure, a single pad area PAD can be disposed on the bezel area BZ. For example, in the display apparatus according to another embodiment of the present disclosure, the second common wiring CL2 can be electrically connected to a same pad area PAD as the first common wiring CL1, as shown in FIG. 18. Thus, in the display apparatus according to another embodiment of the present disclosure, an area of the bezel area BZ can be reduced.

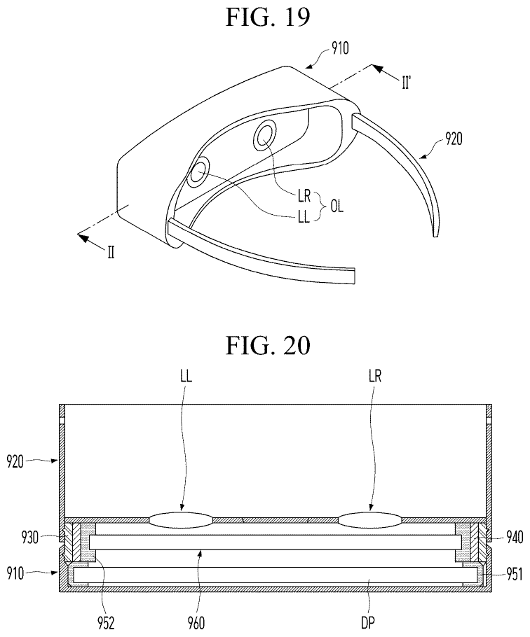

The display apparatus according to another embodiment of the present disclosure can include the display panel DP used in various electronic devices. For example, the display apparatus according to another embodiment of the present disclosure can be a head mounted display (HMD) apparats in which the display panel DP is accommodated in an image element 910 and the image element 910 is fixed in front of the user's eyes by a mounting element 920, as shown in FIGS. 19 and 20. The mounting element 920 can have a shape, such as a leg of a spectacle frame. For example, the mounting element 920 can have a shape extending in a direction from an edge of the image element 910. The mounting element 920 can be coupled to the image element 910 by a coupling element 930. For example, the coupling element 930 can have a plate shape including a region coupled to the image element 910 and a region coupled to the mounting element 920. The coupling element 930 can be disposed inside the image element 910 and the mounting element 920.

Eyepiece lenses OL disposed on a side of the image element 910 can include a left-eye lens LL disposed in front of the user's left eye, and a right-eye lens LR disposed in front of the user's right eye. An empty space can be disposed between the display panel DP and the eyepiece lenses OL. For example, the display panel DP can be disposed close to a first surface of the image element 910, and the left-eye lens LL and the right-eye lens LR can be fixed at a second surface of the image element 910 opposite to the first surface of the image element 910. A gap maintaining element 940 can be disposed inside the coupling element 930 to maintain a space between the display panel DP and the eyepiece lenses OL. The gap maintaining element 940 can be disposed parallel to the coupling element 930. For example, the gap maintaining element 940 can be in direct contact with the coupling element 930.

A first fixing element 951 to fix the display panel DO can be disposed in the image element 910. For example, the first fixing element 951 can be in direct contact with the first surface of the image element 910. Thus, in the display apparatus according to another embodiment of the present disclosure, the movement of the display panel DP and the eyepiece lenses OL according to the user's movement can be effectively prevented. Therefore, in the display apparatus according to another embodiment of the present disclosure, the visibility of the image recognized by the user can be improved.

In the display apparatus according to another embodiment of the present disclosure, the image by the display panel DP and an actual object disposed beyond the first surface of the image element 910 can be provided simultaneously to the user. For example, at least one optical lens 960 can be disposed between the display panel DP and the eyepiece lenses OL. The at least one optical lens 960 can be spaced apart from the display panel DP and the eyepiece lens OL. For example, a second fixing element 952 to fix the at least one optical lens 960 can be disposed in the image element 910. The image by the display panel DP can be displayed on an actual object disposed in front of the user by the at least one optical lens 960. Thus, in the display apparatus according to another embodiment of the present disclosure, an accident due to blocking the user's view can be prevented.

The display apparatus according to another embodiment of the present disclosure is described that the mounting element 920 has a shape, such as a leg of a spectacle frame. However, in the display apparatus according to another embodiment of the present disclosure, the mounting element 920 can have various shapes. For example, in the display apparatus according to another embodiment of the present disclosure, the mounting element 920 can have a head gear shape surrounding the user's head. Thus, in the display apparatus according to another embodiment of the present disclosure, the degree of freedom in a type of the electronic devices in which the display panel DP is used can be improved.

In the result, the display apparatus according to the embodiments of the present disclosure can comprise the planarization layer, the light-emitting devices and the fences on the device substrate, wherein the light-emitting devices can be disposed in the first emission area, the second emission area and the third emission area of each pixel area defined by the fences, wherein each of the light-emitting devices can include the charge generation layer between the first emission stack and the second emission stack, and wherein the planarization layer can include the separation trench disposed between the first emission area and the second emission area of each pixel area and the opening overlapping with the third emission area of each pixel area. Thus, in the display apparatus according to the embodiments of the present disclosure, the charge generation layer of each emission area can be separated by a thickness difference due to the opening and the separation trench. Thereby, in the display apparatus according to the embodiments of the present disclosure, the leakage of the current due to the charge generation layer can be prevented. And, in the display apparatus according to the embodiments of the present disclosure, the production energy can be reduced by process optimization.

The description herein has been presented to enable any person skilled in the art to make, use and practice the technical features of the present disclosure, and has been provided in the context of one or more particular example applications and their example requirements. Various modifications, additions and substitutions to the described embodiments will be readily apparent to those skilled in the art, and the principles described herein may be applied to other embodiments and applications without departing from the scope of the present disclosure. The description herein and the accompanying drawings provide non-limiting examples of the technical features of the present disclosure for illustrative purposes. In other words, the disclosed embodiments illustrate the scope of the technical features of the present disclosure and are not intended to be limiting in any respect. Thus, the scope of the present disclosure is not limited to the embodiments shown, but is to be accorded the widest scope consistent with the claims and their equivalents.

What is claimed is:

1. A display apparatus, comprising:
fences on a device substrate of the display apparatus, the fences defining a first emission area, a second emission area and a third emission area in each pixel area of the display apparatus;
light-emitting devices on the device substrate, the light-emitting devices overlapping with the first emission area, the second emission area and the third emission area of each pixel area; and
a planarization layer between the device substrate and the fences, the planarization layer including a separation trench disposed between the first emission area and the second emission area of each pixel area and an opening overlapping with the third emission area of each pixel area,
wherein each of the light-emitting devices includes a first emission stack, a first charge generation layer and a second emission stack, which are sequentially stacked,
wherein the separation trench separates the first charge generation layer between the first emission area and the second emission area of each pixel area, and
wherein the first charge generation layer between the first emission area and the third emission area of each pixel area and between the second emission area and the third emission area of each pixel area is separated by a thickness difference due to the opening.

2. The display apparatus according to claim 1, wherein light generated by the second emission stack displays a different color from light generated by the first emission stack, and
wherein the first emission area, the second emission area and the third emission area of each pixel area realize different colors.

3. The display apparatus according to claim 1, wherein the second emission area of each pixel area is disposed side by side with the first emission area of a corresponding pixel area in a first direction, and
wherein the third emission area of each pixel area is disposed side by side with the first emission area and the second emission area of a corresponding pixel area in a second direction perpendicular to the first direction.

4. The display apparatus according to claim 3, wherein the separation trench extends in the second direction, and
wherein a length of the separation trench in the second direction is longer than a length of the first emission area of each pixel area in the second direction and is longer than a length of the second emission area of each pixel area in the second direction.

5. The display apparatus according to claim 3, wherein each of the first emission area and the second emission area in each pixel area has a length in the second direction longer than a length in the first direction, and
wherein the third emission area of each pixel area has a length in the second direction shorter than a length in the first direction.

6. The display apparatus according to claim 5, wherein the first charge generation layer in the third emission area of each pixel area is in contact with the first charge generation layer in the third emission area of a pixel area adjacent in the first direction.

7. The display apparatus according to claim 6, further comprising a pad area,
wherein the display apparatus includes a display area in which pixel areas are disposed, and a bezel area disposed outside the display area, and
wherein the first charge generation layer is electrically connected to the pad area in the bezel area.

8. The display apparatus according to claim 1, further comprising:
a first reflective electrode between the device substrate and the light-emitting devices, the first reflective electrode overlapping with the first emission area of each pixel area;
a second reflective electrode between the device substrate and the light-emitting devices, the second reflective electrode overlapping with the second emission area of each pixel area; and
a third reflective electrode between the device substrate and the light-emitting devices, the third reflective electrode overlapping with the third emission area of each pixel area,
wherein the second reflective electrode is disposed on a different layer from the first reflective electrode and the third reflective electrode, and
wherein the third reflective electrode is disposed on a same layer as the first reflective electrode.

9. The display apparatus according to claim 8, further comprising a sub-bank layer between the device substrate and the planarization layer, the sub-bank layer overlapping with the third emission area of each pixel area,
wherein the sub-bank layer includes a penetrating hole overlapping with at least part of the third reflective electrode, and
wherein an edge of the third reflective electrode is covered by the sub-bank layer.

10. The display apparatus according to claim 8, wherein the light-emitting devices include a first light-emitting device overlapping with the first emission area of each pixel area, a second light-emitting device overlapping with the second emission area of each pixel area, and a third light-emitting device overlapping with the third emission area of each pixel area, and
wherein a distance between the third reflective electrode and the third light-emitting device is different from a distance between the first reflective electrode and the first light-emitting device.

11. The display apparatus according to claim 10, wherein a distance between the device substrate and the second light-emitting device is same as a distance between the device substrate and the first light-emitting device, and
wherein a distance between the device substrate and the third light-emitting device is different from the distance between the device substrate and the second light-emitting device.

12. The display apparatus according to claim 10, wherein each of the light-emitting devices includes a first electrode disposed between the device substrate and the first emission stack and a second electrode disposed on the second emission stack,
wherein the first electrode of the second light-emitting device includes a same material as the first electrode of the first light-emitting device,
wherein the first electrode of the third light-emitting device includes a same material as the first electrode of the second light-emitting device, and
wherein a distance between the device substrate and the second electrode of the third light-emitting device is smaller than a distance between the device substrate and the second electrode of the first light-emitting device and is smaller than a distance between the device substrate and the second electrode of the second light-emitting device.

13. The display apparatus according to claim 12, wherein the first electrode of the third light-emitting device is in contact with the third reflective electrode.

14. The display apparatus according to claim 1, wherein each of the light-emitting devices further includes a second charge generation layer in the second emission area, and a third emission stack on the second charge generation layer,
wherein the second charge generation layer in the second emission area of each pixel area is in contact with the second charge generation layer in the first emission area of a corresponding pixel area, and
wherein the second charge generation layer in the third emission area of each pixel area is in contact with the second charge generation layer in the first emission area of a corresponding pixel area and the second charge generation layer in the second emission area of a corresponding pixel area.

15. The display apparatus according to claim 14, wherein the first emission stack is configured to generate light having a first color,
wherein the second emission stack is configured to generate light having a second color,
wherein the third emission stack is configured to generate light having a third color, and
wherein the third color is different from the first color and is different from the second color.

16. The display apparatus according to claim 1, further comprising:
an encapsulation structure on the light-emitting devices;
a first color filter on the encapsulation structure, the first color filter overlapping with the first emission area of each pixel area;
a second color filter on the encapsulation structure, the second color filter overlapping with the second emission area of each pixel area; and
an optical insulating layer on the first color filter and the second color filter,
wherein light passing through the second color filter produces a color that is different from a color produced by light passing through the first color filter, and
wherein the optical insulating layer in the third emission area of each pixel area is in contact with an upper surface of the encapsulation structure which is opposite a lower surface facing to the device substrate.

17. The display apparatus according to claim 1, wherein the third emission area of each pixel area is a blue emission area realizing a blue color.
